(19) United States
(12) Patent Application Publication
(10) Pub. No.: US 2014/0238727 A1
(43) Pub. Date: Aug. 28, 2014

(54) Transparent Conductive Multilayer Electrode And Associated Manufacturing Process

(71) Applicants: Stephane Roger, Saint-Maurice-sur-Fessard (FR); Marie Dieudonne, Laguiole (FR); Gregory Guicheney, Les Leves-et-Thoumeyragues (FR); Phillippe Sonntag, Avon (FR)

(72) Inventors: Stephane Roger, Saint-Maurice-sur-Fessard (FR); Marie Dieudonne, Laguiole (FR); Gregory Guicheney, Les Leves-et-Thoumeyragues (FR); Phillippe Sonntag, Avon (FR)

(73) Assignee: HUTCHINSON, Paris (FR)

(21) Appl. No.: 14/130,156

(22) PCT Filed: Jul. 2, 2012
(86) PCT No.: PCT/EP2012/062853

§ 371 Date: May 14, 2014

(30) Foreign Application Priority Data
Jul. 5, 2011 (FR) FR1102113
Jul. 19, 2011 (FR) FR1102255

(51) Int. Cl. H05K 1/02; H01B 13/00

(52) U.S. Cl. CPC H05K 1/0274; H01B 13/0013; H05K 1/0298; H05K 1/0306
USPC 174/251; 427/108

(57) ABSTRACT

The present invention relates to a multilayer transparent conducting electrode, comprising a substrate layer (1), an adhesion layer (2), a percolating network of metal nanofilaments (3) and an electrical homogenization layer (4), the said electrical homogenization layer (4) comprising:
an elastomer having a glass transition temperature Tg of less than 20° C. and/or a thermoplastic polymer having a glass transition temperature Tg of less than 20° C. and/or a polymer,
an optionally substituted polythiophene conducting polymer, and
nanometric conducting or semiconducting fillers.

The present invention relates to a transparent conducting electrode and to its process of manufacture, in the general field of organic electronics.

Transparent conducting electrodes exhibiting both a high transmission and good electrical conductivity properties are currently the subject of considerable developments in the field of electronic equipment, electrodes of this type being increasingly used for devices such as photovoltaic cells, liquid crystal screens, organic light-emitting diodes (OLEDs) or polymer light-emitting diodes (PLEDs), and also touch screens.

In order to obtain transparent conducting electrodes having a high transmission and good electrical conductivity properties, it is known to have a multilayer transparent conducting electrode comprising, in a first step, a substrate on which are deposited an adhesion layer, a network of metal nanofilaments and an encapsulation layer made of conducting polymer, such as, for example, a blend of poly(3,4-ethylenedioxythiophene) (PEDOT) and poly(sodium styrenesulphonate) (PSS), forming what is known as PEDOT:PSS.

Application US2009/012004 presents a transparent conducting electrode according to this multilayer construction.

However, this type of multilayer transparent conducting electrode composition is not entirely satisfactory, in particular owing to the fact that the encapsulation layer made of PEDOT:PSS, having an acid pH, can oxidize the metal nanofilaments and thus reduce the electrical conductivity of the electrode.

One of the aims of the invention is thus to overcome at least partially the disadvantages of the prior art and to provide a multilayer transparent conducting electrode having a high transmission and good electrical conductivity properties, and also a process for the manufacture thereof.

More particularly, the multilayer transparent conducting electrode according to the invention and obtained according to the process of manufacture according to the invention correspond to the following requirements and properties:
a surface electrical resistance R of less than 1000Ω/,
a mean transmission Tₘₑₐₙ in the visible spectrum of greater than 75%,
an RMS surface roughness of less than 100 nm.

Thus, the present invention relates to a multilayer transparent conducting electrode, comprising a substrate layer, an adhesion layer, a percolating network of metal nanofilaments and an electrical homogenization layer, the electrical homogenization layer comprising:
an elastomer having a glass transition temperature Tg of less than 20° C. and/or a thermoplastic polymer having a glass transition temperature Tg of less than 20° C. and/or a polymer,
an optionally substituted polythiophene conducting polymer, and
nanometric conducting or semiconducting fillers.

According to one aspect of the invention, the electrical homogenization layer also comprises particles of crosslinked or noncrosslinked polymer chosen from functionalized or nonfunctionalized particles of polystyrene, polycarbonate or polymethylenemelamine, the said particles of noncrosslinked polymer exhibiting a glass transition temperature Tg of greater than 80° C., particles of glass, particles of silica and/or particles of metal oxides chosen from the following metal oxides: ZnO, MgO, MgAl₂O₄, or particles of borosilicate.

According to another aspect of the invention, the multilayer transparent conducting electrode exhibits a mean transmission over the visible spectrum of greater than 75%.

According to another aspect of the invention, the multilayer transparent conducting electrode exhibits a surface resistance of less than 1000Ω/□.

According to another aspect of the invention, the adhesion layer is made of nitrile rubber.

According to another aspect of the invention, the percolating network of metal nanofilaments is multilayer.

According to another aspect of the invention, the network of metal nanofilaments has a density of metal nanofilaments of between 0.01 μg/cm² and 1 mg/cm².

According to another aspect of the invention, the metal nanofilaments are nanofilaments of noble metals.

According to another aspect of the invention, the metal nanofilaments are nanofilaments of nonnoble metals.

According to another aspect of the invention, the substrate is chosen from glass and transparent flexible polymers.

The present invention also relates to a process for the manufacture of a multilayer transparent conducting electrode, comprising the following stages:

i) provision of a substrate layer,

ii) application of an adhesion layer,

iii) application of a suspension of metal nanofilaments in an organic solvent to the adhesion layer,

iv) evaporation of the organic solvents from the suspension of metal nanofilaments,

v) application of a composition forming the electrical homogenization layer to the metal nanofilaments and comprising:
(a) at least a dispersion or suspension of elastomer having a glass transition temperature Tg of less than 20° C. and/or of thermoplastic polymer having a glass transition temperature Tg of less than 20° C., and/or a polymer solution,
(b) at least an optionally substituted polythiophene conducting polymer,
(c) nanometric conducting or semiconducting fillers in dispersion or in suspension in water and/or in a solvent,

vi) evaporation of the solvents from the composition forming the electrical homogenization layer by drying at a temperature of between 25 and 80° C., the said drying temperature necessarily having to be, when the polymer particles (c) are particles of noncrosslinked polymer, less than the glass transition temperature Tg of the said particles of noncrosslinked polymer present in the composition applied during the preceding stage, followed by crosslinking of the said electrical homogenization layer.

According to another aspect of the production process, the electrical homogenization layer also comprises particles of crosslinked or noncrosslinked polymer chosen from functionalized or nonfunctionalized particles of polystyrene, polycarbonate or polymethylenemelamine, the said particles of noncrosslinked polymer exhibiting a glass transition temperature Tg of greater than 80° C., particles of glass, particles of silica, and/or particles of metal oxides chosen from the following metal oxides: ZnO, MgO, MgAl₂O₄, or particles of borosilicate.

According to another aspect of the production process, the substrate is chosen from glass and transparent flexible polymers.

According to another aspect of the production process, the adhesion layer is made of nitrile rubber.

According to another aspect of the production process, the stages of application of a suspension of metal nanofilaments to the adhesion layer in an organic solvent and of evaporation of the organic solvents from the suspension of metal nanofilaments are carried out several times in succession in order to obtain a multilayer percolating network of metal nanofilaments.

According to another aspect of the production process, the metal nanofilaments are nanofilaments of noble metals.

According to another aspect of the production process, the metal nanofilaments are nanofilaments of nonnoble metals.

Other characteristics and advantages of the invention will become more clearly apparent on reading the following description, given by ay of illustrative and nonlimiting examples, and the appended drawings, among which:

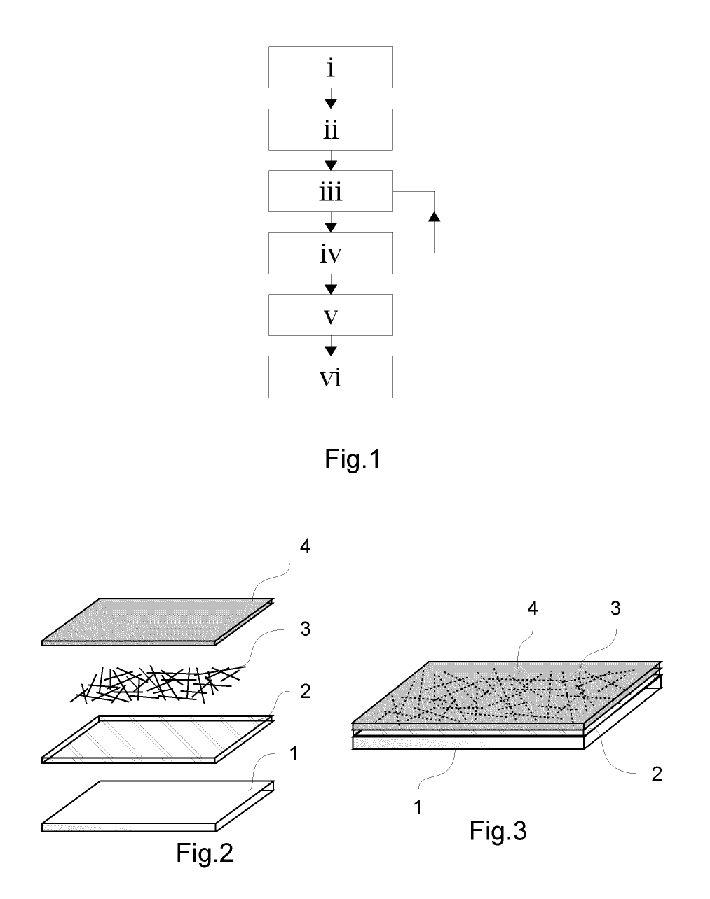

FIG. 1 shows a flow chart of the various stages of the process of manufacture according to the invention,

FIG. 2 shows a diagrammatic representation in exploded view perspective of the various layers of the multilayer transparent conducting electrode,

FIG. 3 shows a diagrammatic representation in perspective of the various layers of the multilayer transparent conducting electrode,

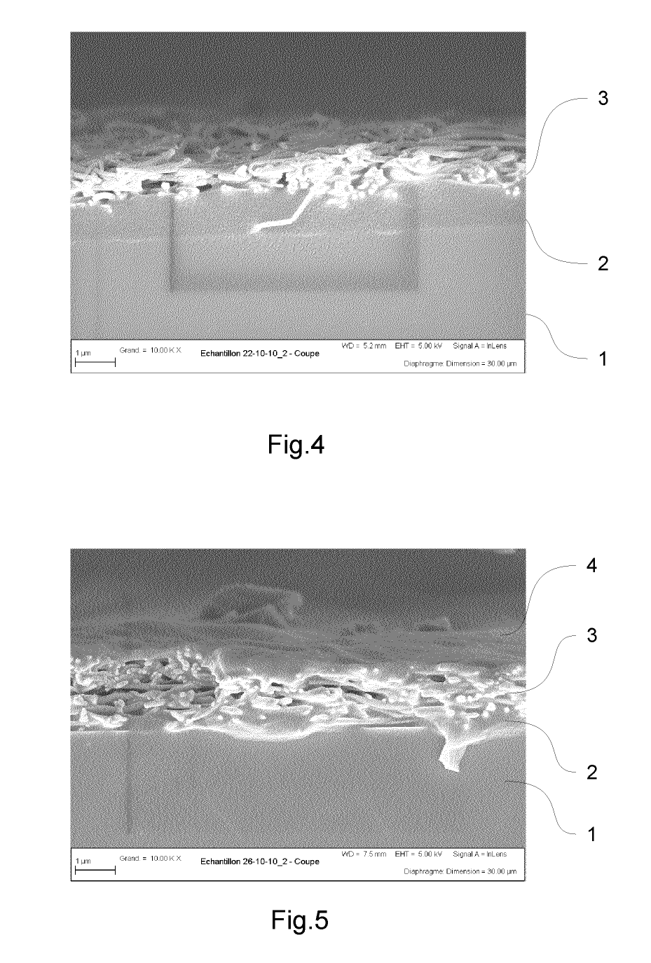

FIGS. 4 and 5 show photographs taken with a scanning electron microscope of a section of a multilayer transparent conducting electrode.

The present invention thus relates to a process for the manufacture of a multilayer transparent conducting electrode, comprising the following stages i), ii), iii), iv) and v).

The stages of the process of manufacture are illustrated in the flow chart of FIG. 1. The various layers resulting from these stages are also visible in FIGS. 2 to 5.

### i) Provision of a Substrate Layer 1

During this first stage i) of the process of manufacture of a transparent conducting electrode, the substrate 1 on which the upper layers will be supported is provided.

In order to retain the transparent nature of the electrode, this substrate 1 must be transparent. It can be flexible or rigid and can advantageously be chosen from glass, in the case where it has to be rigid, or else chosen from transparent flexible polymers, such as polyethylene terephthalate (PET), polyethylene naphthalate (PEN), polyethersulphone (PES), polycarbonate (PC), polysulphone (PSU), phenolic resins, epoxy resins, polyester resins, polyimide resins, polyetherester resins, polyetheramide resins, polyvinyl acetate, cellulose nitrate, cellulose acetate, polystyrene, polyolefins, polyamide, aliphatic polyurethanes, polyacrylonitrile, polytetrafluoroethylene (PTFE), polymethyl methacrylate (PMMA), polyarylate, polyetherimides, polyetherketones (PEKs), polyetheretherketones (PEEKs) and polyvinylidene fluoride (PVDF), the most preferred flexible polymers being polyethylene terephthalate (PET), polyethylene naphthalate (PEN) and polyethersulphone (PES).

### ii) Application of an Adhesion Layer

During this second stage ii), the substrate 1 is covered with an adhesion layer 2. This adhesion layer 2 has the aim of improving the adhesion between the substrate 1 and the layer above the said adhesion layer 2.

This adhesion layer 2 is also transparent, in order to retain a high transmission, and sufficiently resistant to the application of the layer surmounting it, in particular if this application involves solvents. The adhesion layer 2 can be, in particular if the substrate is flexible, itself also made of a flexible material, for example of nitrile rubber (NBR), styrene/butadiene (SBR), natural rubber (NR) or also of polymer solutions or other latexes, such as polyvinyl acetate (PVA), polyurethane (PU) or polyvinylpyrrolidone (PVP).

The adhesion layer 2 can be deposited on the substrate 1 according to any method known to a person skilled in the art, the most widely used techniques being spray coating, inkjet coating, dip coating, film drawer coating, spin coating, impregnation coating, slot die coating, scraper coating or flexographic coating, this coating being followed by a phase of drying and crosslinking the said adhesion layer 2.

### iii) Application of a Suspension of Metal Nanofilaments 3 in an Organic Solvent to the Adhesion Layer 2

During this third stage iii), a suspension of metal nanofilaments 3 is applied to the adhesion layer 2.

These metal nanofilaments 3 are dispersed beforehand in a readily evaporatable organic solvent (for example ethanol) or also dispersed beforehand in an aqueous medium in the presence of a surfactant (preferably an ionic conductor). It is this suspension of metal nanofilaments 3 in a solvent which is applied to the adhesion layer 2.

The metal nanofilaments 3 can be composed of noble metals, such as, for example, silver, gold or platinum.

The metal nanofilaments 3 can also be composed of nonnoble metals, such as, for example, copper, iron or nickel.

In the same way as the adhesion layer 2, the suspension of metal nanofilaments 3 can be deposited on a substrate 1 according to any method known to a person skilled in the art, the most widely used techniques being spray coating, inkjet coating, dip coating, film drawer coating, spin coating, impregnation coating, slot die coating, scraper coating or flexographic coating.

### iv) Evaporation of the Organic Solvents from the Suspension of Metal Nanofilaments 3

During this fourth stage iv), the solvents of the suspension of metal nanofilaments 3 are evaporated in order to form a percolating network of metal nanofilaments 3 which allows the current to pass through.

The quality of the dispersion of the metal nanofilaments 3 in the suspension conditions the quality of the network formed after evaporation. For example, the concentration of the dispersion can be between 0.01 wt % and 10 wt %, preferably between 0.1 wt % and 2 wt %, in the case of a percolating network produced in a single pass.

The quality of the network formed after evaporation is also defined by the density of metal nanofilaments 3 present in the network, this density being between 0.01 μg/cm² and 1 mg/cm², preferably between 0.01 μg/cm² and 10 μg/cm².

The final network can be composed of several superimposed layers of metal nanofilaments 3. For this, it is sufficient to repeat stages iii) and iv) as many times as desired to obtain layers of metal nanofilaments 3. For example, the network of metal nanofilaments 3 can comprise from 1 to 800 superimposed layers, preferably less than 100 layers, with a 0.1 wt % dispersion of metal nanofilaments 3.

FIG. 4 shows a photograph taken by an electron microscope of a multilayer transparent conducting electrode resulting from the preceding stages. The multilayer transparent conducting electrode here comprises a substrate layer 1, an adhesion layer 2 made of nitrile rubber and a network of metal nanofilaments 3 formed of 15 layers.

### v) Application of a Composition Forming the Electrical Homogenization Layer 4

During this fifth stage v), the composition is applied to the network of metal nanofilaments 3, which composition is intended to form an electrical homogenization layer 4 of said network of metal nanofilaments 3.

Thus, the composition forming the electrical homogenization layer 4 comprises:

(a) at least a dispersion or suspension of elastomer having a glass transition temperature Tg<20° C. and/or of thermoplastic polymer having a glass transition temperature Tg<20 C., and/or a polymer solution,

(b) at least an optionally substituted poly conducting polymer,

(c) conducting or semiconducting fillers which are nanometric in one or two dimensions, in dispersion or in suspension in water and/or in a solvent, the said fillers preferably exhibiting a form factor (length/diameter ratio)>10.

The electrical homogenization layer 4 can also comprise:

(d) particles of crosslinked or noncrosslinked polymer chosen from functionalized or nonfunctionalized particles of polystyrene, polycarbonate or polymethylenemelamine, the said particles of noncrosslinked polymer exhibiting a glass transition temperature Tg>80° C., particles of glass, particles of silica, and/or particles of metal oxides chosen from the following metal oxides: ZnO, MgO or MgAl₂O₄, or particles of borosilicate, it being possible for the said particles (d) to be provided either in the powder form or in the form of a dispersion in water and/or in a solvent.

The composition forming the electrical homogenization layer 4 can comprise each of the constituents (a), (b), (c) and (d) in the following proportions by weight (for a total of 100% by weight):

(a) from 5 to 99% by weight and preferably from 50 to 99% by weight of at least a dispersion or suspension of elastomer having a glass transition temperature Tg<20 ° C. and/or of thermoplastic polymer having a glass transition temperature Tg<20° C., and/or a polymer solution,

(b) from 0.01 to 90% by weight and preferably from 0.1 to 20% by weight of at least an optionally substituted polythiophene conducting polymer,

(c) from 0.01 to 90% by weight and preferably from 0.1 to 10% by weight of conducting or semiconducting fillers which are nanometric in one or two dimensions, in dispersion or in suspension in water and/or in a solvent,

(d) from 0.1 to 90% by weight and preferably from 1 to 50% by weight of particles of crosslinked or noncrosslinked polymer chosen from functionalized or nonfunctional particles of polystyrene, polycarbonate or polymethylenemelamine, said particles of noncrosslinked polymer exhibiting a glass transition temperature Tg>80° C., of particles of glass, of particles of silica, and/or or particles of metal oxides chosen from the following metal oxides: ZnO, MgO or MgAl₂O₄, or particles of borosilicate.

According to an advantageous embodiment, the composition forming the electrical homogenization layer 4 comprises at least a dispersion or suspension (a) of elastomer, said elastomer preferably being chosen from polybutadiene, polyisoprene, acrylic polymers, polychloroprene, it being possible for the latter to optionally be a sulphonated polychloroprene, polyurethane, hexafluoropropene/difluoropropene/tetrafluoroethylene terpolymers, copolymers based on chlorobutadiene and on methacrylic acid or based on ethylene and on vinyl acetate, SBR (styrene butadiene rubber), SBS (styrene butadiene styrene), SIS (styrene isoprene styrene) and SEBS (styrene ethylene butylene styrene) copolymers, isobutylene/isoprene copolymers, butadiene/acrylonitrile copolymers or butadiene/acrylonitrile/methacrylic acid terpolymers. More preferably still, the elastomer is chosen from acrylic polymers, polychloroprene, SBR copolymers and butadiene/acrylonitrile copolymers.

According to another advantageous embodiment, the composition forming the electrical homogenization layer 4 can comprise at least a dispersion or suspension (a) of thermoplastic polymer, said thermoplastic polymer being chosen from polyesters, polyamides, polypropylene, polyethylenes, chlorinated polymers, such as polyvinyl chloride and polyvinylidene chloride, fluorinated polymers, such as polyvinylidene fluoride (PVDF), polyacetates, polycarbonates, polyetheretherketones (PEEKs), polysulphides or ethylene/vinyl acetate copolymers.

According to another preferred embodiment, the composition forming the electrical homogenization layer 4 can comprise at least a polymer solution (a), the said polymer being chosen from polyvinyl alcohols (PVOHs), polyvinyl acetates (PVAs), polyvinylpyrrolidones (PVPs) or polyethylene glycols.

The said elastomer and/or the said thermoplastic polymer are used in the form of a dispersion or of a suspension in water and/or in a solvent, said solvent preferably being an organic solvent chosen from dimethyl sulphoxide (DMSO), N-methyl-2-pyrrolidone (NMP), ethylene glycol, tetrahydrofuran (THF), dimethyl acetate (DMAc) or dimethylformamide (DMF). Preferably, the elastomer and/or the thermoplastic polymer are in dispersion or in suspension in water.

The conducting polymer (b) is a polythiophene, the latter being one of the more stable polymers thermally and electronically. A preferred conducting polymer is poly(3,4-ethylenedioxythiophene)-poly(styrenesulphonate) (PEDOT:PSS), the latter being stable to light and to heat, easily dispersed in water and not exhibiting any environmental disadvantages.

The conducting polymer (b) can be provided in the form of granules or of a dispersion or suspension in water and/or in a solvent, said solvent preferably being a polar organic solvent chosen from dimethyl sulphoxide (DMSO), N-methyl-2-pyrrolidone (NMP), ethylene tetrahydrofuran (THF), dimethyl acetate (DMAc) or dimethylformamide (DMF), the conducting polymer (b) preferably being in dispersion or in suspension in water, dimethyl sulphoxide (DMSO) or ethylene glycol.

Organic compounds also known as “conductivity enhancers”, the latter making it possible to improve the electrical conductivity of the conducting polymer, can also be added to the composition forming the electrical homogenization layer 4. These compounds can in particular carry dihydroxyl, polyhydroxyl, carboxyl, amide and/or lactam functional groups, such as the compounds mentioned in patents U.S. Pat. No. 5,766,515 and U.S. Pat. No. 6,984,341, which are incorporated here by way of reference. The most preferred organic compounds or “conductivity enhancers” are DMSO (dimethyl sulphoxide), sorbitol, ethylene glycol and glycerol.

The fillers (c) can be conducting fillers chosen from nanoparticles and/or nanofilaments of silver, gold, platinum and/or ITO (indium tin oxide), and/or semiconducting fillers chosen from carbon nanotubes and graphene-based nanoparticles. According to a preferred embodiment, the fillers (c) are carbon nanotubes in dispersion in water and/or in a solvent chosen from the following polar organic solvents: dimethyl sulphoxide (DMSO), N-methyl-2-pyrrolidone (NMP), ethylene glycol, dimethyl acetate (DMAc), dimethylformamide (DMF), acetone and alcohols, such as methanol, ethanol, butanol and isopropanol, or a mixture of these solvents.

According to a particularly preferred embodiment of the composition forming the electrical homogenization layer 4, the particles of crosslinked or noncrosslinked polymer (d) have a mean diameter of between 30 and 1000 nm, and more preferably still are chosen from polystyrene particles having a mean diameter of between 30 and 1000 nm. The distribution in the sizes of these polymer particles can be multimodal and preferably bimodal.

The said polymer particles (d) can be used in the form of a powder or of a dispersion or suspension in water and/or in a solvent chosen from the following polar organic solvents: dimethyl sulphoxide (DMSO), N-methyl-2-pyrrolidone (NMP), ethylene glycol, dimethyl acetate (DMAc), dimethylformamide (DMF), acetone and alcohols, such as methanol, ethanol, butanol and isopropanol, or a mixture of these solvents.

The ratio by weight of the elastomer and/or thermoplastic polymer and/or polymer (a) to the particles (d) can be between 0.1 and 10 000 and preferably between 1 and 1000. The ratio by weight of the conducting polymer (b) to the particles (d) can, for its part, be between 0.01 and 10 000, and preferably between 0.1 and 500. As regards the ratio by weight of the elastomer and/or thermoplastic polymer and/or polymer (a) to the nanometric conducting or semiconducting fillers (c), this ratio can be between 1 and 1000 and preferably between 50 and 500. All the ratios by weight indicated are given as weight of dry matter.

Additives, such as ionic or nonionic surfactants, wetting agents, rheological agents, such as thickening agents or liquefying agents, adhesion promoters, dyes or crosslinking agents, can also be added to the composition of the invention in order to improve or modify the performance thereof according to the final application targeted.

Like the adhesion layer 2 and the suspension of metal nanofilaments 3, the electrical homogenization layer 4 can be deposited on a support according to any method known to a person skilled in the art, the most widely used techniques be spray coating, inkjet coating, dip coating, film drawer coating, spin coating, impregnation coating, slot die coating, scraper coating or flexographic coating, this being done so as to obtain a film having a thickness which can be between 50 nm and 15 μm.

### vi) Evaporation of the Solvents from the Composition Forming the Electrical Homogenization Layer 4

During this sixth stage vi), the solvents of the composition forming the electrical homogenization layer 4 are evaporated by drying.

Preferably, this drying is carried out at a temperature of between 25 and 80° C., said drying temperature necessarily having to be, when the polymer particles (d) are noncrosslinked polymer particles, less than the glass transition temperature Tg of said noncrosslinked polymer particles present in the composition applied during the preceding stage.

The electrical homogenization layer 4 is also subjected to crosslinking during this stage, for example by vulcanization at a temperature of 150° C. for a time of 5 minutes.

FIG. 5 shows a photograph, taken using a scanning electron microscope, of a multilayer transparent conducting electrode resulting from the preceding stages. The multilayer transparent conducting electrode thus comprises a substrate layer 1, an adhesion layer 2 made of nitrile rubber, a network of metal nanofilaments 3 formed of 15 layers, and an electrical homogenization layer 4.

Another subject matter of the invention is thus also a multilayer transparent conducting electrode, this type of electrode preferably having a thickness of between 0.5 μm and 20 μm.

This multilayer transparent conducting electrode is represented in FIGS. 2, 3 and 5 and comprises a substrate layer 1, an adhesion layer 2, a network of metal nanofilaments 3 and an electrical homogenization layer 4, the said electrical homogenization layer 4 comprising:
an elastomer having a glass transition temperature Tg of less than 20° C. and/or a thermoplastic polymer having a glass transition temperature Tg of less than 20° C. and/or a polymer,
an optionally substituted polythiophene conducting polymer,
nanometric conducting or semiconducting fillers.

The electrical homogenization layer 4 can also comprise particles of crosslinked or noncrosslinked polymer chosen from functionalized or nonfunctionalized particles of polystyrene, polycarbonate or polymethylenemelamine, said particles of noncrosslinked polymer exhibiting a glass transition temperature Tg of greater than 80° C., particles of glass, particles of silica, and/or particles of metal oxides chosen from the following metal oxides: ZnO, MgO, MgAl₂O₄, or particles of borosilicate.

This multilayer transparent conducting electrode, resulting in particular from the process of manufacture described above, thus exhibits a high transmission, a low surface electrical resistance and a low roughness of less than 100 nm.

In the organic electronic sector, the devices are generally multilayer devices. The multilayer transparent conducting electrode according to the invention makes up one of these extremely thin layers. Thus, in order to minimize the risks of short circuit in the multilayer device, it is essential to have the lowest possible roughness.

The substrate layer 1, in order to retain the transparent nature of the electrode, has to be transparent. The said substrate layer 1 can be flexible or rigid and can advantageously be chosen from glass, in the case where it has to be rigid, or else chosen from transparent flexible polymers, such as polyethylene terephthalate (PET), polyethylene naphthalate (PEN), polyethersulphone (PES), polycarbonate (PC), polysulphone (PSU), phenolic, epoxy, polyester, polyimide, polyetherester and polyetheramide resins, polyvinyl acetate, cellulose nitrate, cellulose acetate, polystyrene, polyolefins, polyamide, aliphatic polyurethanes, polyacrylonitrile, polytetrafluoroethylene (PTFE), polymethyl methacrylate (PMMA), polyarylate, polyetherimides, polyetherketones (PEKs), polyetheretherketones (PEEKs) and polyvinylidene fluoride (PVDF), the most preferred flexible polymers being polyethylene terephthalate (PET), polyethylene naphthalate (PEN) and polyethersulphone (PES).

The adhesion layer 2 is also transparent, in order to retain a high transmission, and sufficiently resistant to the application of the layer surmounting it, in particular if this application involves solvents. The adhesion layer 2 can be, in particular if the substrate is flexible, itself also made from a flexible material, for example of nitrile rubber (NBR).

The network of metal nanofilaments 3 can be composed of noble metals, such as, for example, silver, gold or platinum. It can also be composed of nonnoble metals, such as, for example, copper, iron or nickel.

The network of metal nanofilaments 3 can be composed of one or more superimposed layers of metal nanofilaments 3, thus forming a conducting percolating network, and can have a density of metal nanofilaments 3 of between 0.01 μg/cm² and 1 mg/cm².

The elastomers which may be present in the electrical homogenization layer 4 are preferably chosen from polybutadiene, polyisoprene, acrylic polymers, polychloroprene, it being possible for the latter to optionally be a sulphonated polychloroprene, polyurethane, hexafluoropropene/difiuoropropene/tetrafluoroethylene terpolymers, copolymers based on chlorobutadiene and on methacrylic acid or based on ethylene and on vinyl acetate, SBR (styrene butadiene rubber), SBS (styrene butadiene styrene), SIS (styrene isoprene styrene) and SEBS (styrene ethylene butylene styrene) copolymers, isobutylene/isoprene copolymers, butadiene/acrylonitrile copolymers or butadiene/acrylonitrile/methacrylic acid terpolymers. More preferably still, the elastomer is chosen from acrylic polymers, polychloroprene, SER copolymers and butadiene/acrylonitrile copolymers.

According to another advantageous structure, the electrical homogenization layer 4 can comprise at least one thermoplastic polymer, said thermoplastic polymer being chosen from polyesters, polyamides, polypropylene, polyethylene, chlorinated polymers, such as polyvinyl chloride and polyvinylidene chloride, fluorinated polymers, such as polyvinylidene fluoride (PVDF), polyacetates, polycarbonates, polyetheretherketones (PEEKs), polysulphides or ethylene/vinyl acetate copolymers.

According to another preferred structure, the electrical homogenization layer 4 can comprise at least one polymer, said polymer being chosen from polyvinyl alcohols (PVDF), polyvinyl acetates (PVAs), polyvinylpyrrolidones (PVPs) or polyethylene glycols.

The conducting polymer which may be present in the electrical homogenization layer 4 is preferably a polythiophene, the latter being one of the more stable polymers thermally and electronically. A preferred conducting polymer is poly(3,4-ethylenedioxythiophene)-poly(styrenesulphonate) (PEDOT:PSS), the latter being stable to light and to heat, easily dispersed in water and not exhibiting any environmental disadvantages.

Organic compounds also known as “conductivity enhancers”, the latter making it possible to improve the electrical conductivity of the conducting polymer, can also be included in the electrical homogenization layer 4. These compounds can in particular carry dihydroxyl, polyhydroxyl, carboxyl, amide and/or lactam functional groups, such as the compounds mentioned in patents U.S. Pat. No. 5,766,515 and U.S. Pat. No. 6,984,341, which are incorporated here by way of reference. The most preferred organic compounds or “conductivity enhancers” are sorbitol, ethylene glycol, glycerol or DMSO (dimethyl sulphoxide).

The particles of crosslinked or noncrosslinked polymer which may be present in the electrical homogenization layer 4 preferably have a mean diameter of between 30 and 1000 nm and more preferably still are chosen from polystyrene particles having a mean diameter of between 30 and 1000 nm. The distribution in the sizes of these polymer particles can be multimodal and preferably bimodal.

The conducting fillers which may be present in the electrical homogenization layer 4 are preferably chosen from nanoparticles and/or nanofilaments of silver, gold, platinum and/or ITO (indium tin oxide), and/or semiconducting fillers chosen from carbon nanotubes and graphene-based nanoparticles.

The ratio by weight of the elastomer and/or thermoplastic polymer and/or polymer to the particles can be between 0.1 and 10 000 and preferably between 1 and 1000. The ratio by weight of the conducting polymer to the particles can, for its part, be between 0.01 and 10 000, and preferably between 0.1 and 500. As regards the ratio by weight of the elastomer and/or thermoplastic polymer and/or polymer to the nanometric conducting or semiconducting fillers, this ratio can be between 1 and 1000 and preferably between 50 and 500. All the ratios by weight indicated are given as weight of dry matter.

The following experimental results show values obtained by a multilayer transparent conducting electrode according to the invention for essential parameters, such as the transmission at the wavelength of 550 nm T₅₅₀, the mean transmission Tₘₑₐₙ, the surface electrical resistance R and the density of metal nanofilaments.

These results are compared with values obtained for multilayer transparent conducting electrodes resulting from Application US 2009/012004.

### 1) Experimental Conditions

Unless otherwise mentioned, the tests were carried out on an electrode comprising only a single layer of silver nanofilaments and the electrical homogenization layer of which comprises:
an elastomer having a glass transition temperature Tg of less than 20° C. and/or a thermoplastic polymer having a glass transition temperature Tg of less than 20° C. and/or a polymer,
an optionally substituted polythiophene conducting polymer,
nanometric conducting or semiconducting fillers.

Just one rigid substrate was used to prepare the electrodes: a glass sheet.

The various layers were all applied by a similar spin coating method.

### 2) Methodology of the Measurements

### Measurement of the Total Transmission

The total transmission, that is to say the light intensity passing through the film over the visible spectrum, is measured on 50×50 mm test specimens using a PerkinElmer Lambda 35 spectrophotometer over a UV/visible spectrum [300 nm-900 nm].

Two transmission values are recorded:
the transmission value at 550 nm T₅₅₀ and
the mean transmission value Tₘₑₐₙ over the entire visible spectrum, this value corresponding to the mean value of the transmissions over the visible spectrum. This value is measured every 10 nm.

### Measurement Surface Electrical Resistance

The surface electrical resistance (in Ω/□) can be defined by the following formula:

$$R - \frac{ρ}{e} - \frac{1}{σ \cdot e}$$

e: thickness of the conducting layer (in cm),
σ: conductivity of the layer (in S/cm)(σ=1/ρ),
ρ: resistivity of the layer (in Ω cm).

The surface electrical resistance is measured on 20>20 mm test specimens using a Keithley 2400 SourceMeter ohmmeter and two points to carry out the measurements. Gold contacts are deposited beforehand on the electrode by CVD in order to facilitate the measurements.

### Measurements of Surface Roughness

The mean roughness Rq is measured using an atom force microscope (AFM) (Digital Instrument Dimension 3100) in tapping mode on 50×50 mm test specimens.

The measurements are carried out twice on each test specimen.

### Measurements of Density of Silver Nanofilaments

The density of nanofilaments is determined by image analysis using photographs obtained after observation of the test specimens using a scanning electron microscope (field emission Supra 35©, Zeiss). The overall area of the photographs is 78 506 μm² (acceleration voltage 28 kV, diaphragm 60 μm, magnification 1000×). Chemical contrast image processing with the Visilog© (version 6.9) software is carried out on 10 photographs per test specimen. Characterization is carried out according to two “maximum” and “minimum” algorithms.

The density of the nanofilaments is defined by the following formula:

$$Weight per unit of surface area = 234.675 \times {10}^{- 2} \times \frac{A}{O A}$$

with:
Weight per unit of surface area in g/cm²
A: area of the nanofilaments calculated by Visilog
OA: overall area of the SEM image (78 560 μm²)

### 3) Results

### Comparative Results of the Total Transmission and of Surface Electrical Resistance

### Key:

NBR: nitrile her
PVP: polyvinylpyrrolidone
PVA: polyvinyl alcohol
PU: polyurethane
NWs: network of metal nanofilaments
PEDOT:PSS: polythiophene (conducting polymer)
TCO Hutchinson©: electrical homogenization layer according to the invention.

| | | | | Minimum | Maximum | |
|---|---|---|---|---|---|---|
| | | | | density of | density of | |
| | | | | NWs | NWs | |
| Electrode structure | T₅₅₀ (%) | Tₘₑₐₙ (%) | R (Ω/□) | (μg/cm²) | (μg/cm²) | Comments |
| NBR/NWs | 92 | 91 | NC | 0.03 | 0.01 | State of the art |
| | | | | | | US2009/012004 |
| NBR/NWs/PEDOT:PSS | 72 | 70 | 1425 | 0.05 | 0.14 | State of the art |
| | | | | | | US2009/012004 |
| NWs glass/PEDOT:PSS | 85 | 83 | 225 000 | 0.29 | 0.70 | State of the art |
| | | | | | | US2009/012004 |
| NWs/NBR/PEDOT:PSS | 88 | 86 | 144 000 | 0.05 | 0.18 | State of the art |
| | | | | | | US2009/012004 |
| PVP/NWs | 93 | 91 | NC | 0.08 | 0.25 | State of the art |
| | | | | | | US2009/012004 |
| PVP/NWs/PEDOT:PSS | 82 | 79 | 47 600 000 | 0.02 | 0.04 | State of the art |
| | | | | | | US2009/012004 |
| NWs/PVP/PEDOT:PSS | 78 | 73 | 196 000 000 | 0.04 | 0.17 | State of the art |
| | | | | | | US2009/012004 |
| NWs/PU | 92 | 90 | NC | 0.005 | 0.009 | State of the art |
| | | | | | | US2009/012004 |
| NWs/PU/PEDOT:PSS | 89 | 86 | 5 200 000 | 0.01 | 0.04 | State of the art |
| | | | | | | US2009/012004 |
| PVA/NWs/PEDOT:PSS | 88 | 86 | 64 400 000 | 0.02 | 0.08 | State of the art |
| | | | | | | US2009/012004 |
| NWs + PVA/PEDOT:PSS | 90 | 88 | 41 500 000 | 0.005 | 0.01 | State of the art |
| | | | | | | US2009/012004 |
| NBR/NWs/TCO | 91 | 89 | 776 | 0.005 | 0.01 | Electrode according to |
| Hutchinson © | | | | | | the invention |

It is thus apparent that an electrode according to the invention comprising only a single layer of metal nanofilaments has a high transmission, of greater than 75% for the T₅₅₀ and 75% for the Tₘₑₐₙ, and a surface electrical resistance R of less than 1000Ω/□, of the order of 776Ω/□.

Thus, at the same transmission, the surface electrical resistance R of the multilayer transparent conducting electrode according to the invention is much better than those of the prior art, the electrical homogenization layer not resulting in a significant increase in the surface electrical resistance, in particular as a result of the oxidation of the metal nanofilaments by encapsulation by a simple PEDOT:PSS layer.

### Results of the Measurements of Densities, Transmission and Surface Electrical Resistance as a Function of the Number of Layers of Nanofilaments

The measurements were carried out on multilayer transparent conducting electrodes according to the invention, comprising:
an adhesion layer of nitrile rubber,
a multilayer network of silver nanofilaments,
an electrical homogenization layer according to the invention, TCO Hutchinson©.

| | | | | Density of Ag | |
|---|---|---|---|---|---|
| Number of | | | | nanofilaments (μg/cm²) | |
| layers of Ag | | Tₘₑₐₙ | R | Minimum | Maximum |
| nanofilaments | Tₛ₅₀ (%) | (%) | (Ω/□) | density | density |
| 10 | 78 | 76 | 12 | 0.28 | 0.68 |
| 8 | 78 | 77 | 12 | 0.29 | 0.67 |
| 6 | 81 | 80 | 16 | 0.16 | 0.45 |
| 4 | 82 | 80 | 20 | 0.13 | 0.36 |
| 2 | 88 | 87 | 177 | 0.10 | 0.24 |

It is thus apparent that, for multilayer transparent conducting electrodes according to the invention, a high number of layers of silver nanofilaments at densities of between 0.10 and 0.7 μg/cm² makes it possible to greatly reduce the values of surface electrical resistance R while retaining high transmission values, of greater than 75% for T₅₅₀ and 75% for Tₘₑₐₙ.

### 4) Examples

### Example A

This example corresponds to a multilayer transparent conducting electrode according to the state of the art, without an electrical homogenization layer 4.

A composition A is prepared in the following way:
2 g of NBR (Nitrile Butadiene Rubber Synthomer, 5130®), self-crosslinking and diluted beforehand to 15% with deionized water, are deposited on a planarized PET plastic substrate (Dupont de Nemour, ST504) using a spin coater (SPS, SPIN 150), according to the following parameters: acceleration 300 rpm, speed 3000 rpm for 100 s. The latex film is subsequently vulcanized at 150° C. for 5 min using an oven.
2 g of a dispersion of silver nanofilaments at a concentration of 0.16% by weight in ethanol (Bluenano, SLV-NW-90) are subsequently deposited on the vulcanized latex layer by spin coating (acceleration: 500 rpm, speed: 5000 rpm, time 100 s). This operation is repeated 6 times (6 layers of silver nanofilaments) in order to form a percolating network of silver nanofilaments.

The properties of the transparent and conducting electrode are as follows:

| Properties | Results | |
|---|---|---|
| Transmission (550 nm, | 84% | |
| %) | | |
| Transmission (mean | 83% | |
| over the visible range 400-1000 nm, | | |
| %) | | |
| Surface resistance (Ω/□) | 630 | Ω/□ |
| Density of silver | 0.1 | μg/cm² |
| nanofibres (dₘᵢₙ, μg/cm²) | | |
| Density of silver | 0.36 | μg/cm² |
| nanofibres (dₘₐₓ, μg/cm²) | | |

### Example B

This example corresponds to a multilayer transparent conducting electrode according to the invention, with an electrical homogenization layer 4.

A composition B is prepared in the following way:
2 g of NBR (Nitrile Butadiene Rubber, Synthomer, 5130®), self-crosslinking and diluted beforehand to 15% with deionized water, are deposited on a planarized PET plastic substrate (Dupont de Nemour, ST504) using a spin coater (SPS, SPIN 150), according to the following parameters: acceleration 200 rpm, speed 2000 rpm for 100 s. The latex film is subsequently vulcanized at 150° C. for 5 min using an oven.
2 g of a dispersion of silver nanofilaments at a concentration of 0.16% by weight in ethanol (Bluenano, SLV-NW-90) are subsequently deposited on the vulcanized latex layer by spin coating (acceleration: 500 rpm, speed: 5000 rpm, time 100 s). This operation is repeated 6 times (6 layers of silver nanofilaments) in order to form a percolating network of silver nanofilaments.
8.5 mg of Graphistrength C100® MWNT carbon nanotubes are dispersed in 14.17 g of a Clevios PH1000® PEDOT:PSS dispersion having a solids content of 1.2% and in 17.00 g of DMSO using a high-shear mixer (Silverson L5M) at a speed of 8000 revolutions/minute for 2 hours.
31.18 g of the dispersion of carbon nanotubes prepared above are added to 3.76 g of a Synthomer 5130® NBR (Nitrite Butadiene Rubber) elastomer in suspension in water (solids content of 45%). The mixture is subsequently stirred using a magnetic bar for 30 minutes.
The mixture obtained is subsequently filtered using a stainless steel mesh (Ø=50 μm), this being done in order to remove the dust and the large aggregates of carbon nanotubes which were not dispersed.
The mixture is subsequently applied to the percolating network of silver nanofilaments using the SPIN 150 spin coater (acceleration: 500 rpm, speed 5000 rpm, time 100 s). The latter is vulcanized at 150° C. for a time of 5 minutes.

The properties of the transparent and conducting electrode are as follows:

| Properties | Results | |
|---|---|---|
| Transmission (550 nm, %) | 82% | |
| Transmission (mean over the visible range | 80% | |
| 400-1000 nm, %) | | |
| Surface resistance (Ω/□) | 38 | Ω/□ |
| Density of silver nanofibres (dₘᵢₙ, μg/cm²) | 0.19 | μg/cm² |
| Density of silver nanofibres (dₘₐₓ, μg/cm²) | 0.83 | μg/cm² |

### Example C

This example corresponds to a multilayer transparent conducting electrode according to the invention, with an electrical homogenization layer 4 composing crosslinked particles.

A composition C is prepared in the following way:
2 g of NBR (Nitrile Butadiene Rubber, Synthomer, 5130®), self crosslinking and diluted beforehand to 15% with deionized water, are deposited on a planarized PET plastic substrate (Dupont de Nemour, ST504) using a spin coater (SPS, SPIN 150), according to the following parameters: acceleration 200 rpm, speed 2000 rpm for 100 s. The latex film is subsequently vulcanized at 150° C. for 5 min using an oven.
2 g of a dispersion of silver nanofilaments at a concentration of 0.16% by weight in ethanol (Bluenano, SLV-NW-90) are subsequently deposited on the vulcanized latex layer by spin coating (acceleration: 500 rpm, speed: 5000 rpm, time 100 s). This operation is repeated 6 times (6 layers of silver nanofilaments) in order to form a percolating network of silver nanofilaments.
8.5 mg of Graphistrength U100® MWNT carbon nanotubes are dispersed in 14.17 g of a Clevios PH500® PEDOT:PSS dispersion having a solids content of 1.2% and in 17.00 g of DMSO using a high-shear mixer (Silverson L5M) at a speed of 8000 revolutions/minute for 2 hours.
0.311 g of polystyrene nanoparticles PS00150-NS (Ø=150 nm) and 0.078 g of polystyrene nanoparticles PS00600-NS (Ø=600 nm) are added to the dispersion prepared above (80% PS00150-NS and 20% PS00600-NS) and then dispersed using a high-shear mixer (Silverson L5M) at a speed of 8000 revolutions/minute for 20 minutes.
31.58 g of the dispersion of carbon nanotubes prepared above and 0.475 g of deionized water are added to 289 g of a Synthomer 5130® NBR (Nitrile Butadiene Rubber) elastomer (Tg=−40° C.) in suspension in water (solids content of 45%). The mixture is subsequently stirred using a magnetic bar for 30 minutes. 23% of the dry latex nanoparticles are replaced with the mixture of polystyrene nanoparticles in the proportions mentioned above (80% PS00150-NS and 20% PS00600-NS).
The mixture obtained is subsequently filtered using a stainless steel mesh (Ø=50 μm), this being done in order to remove the dust and the large aggregates of carbon nanotubes which were not dispersed.
The mixture is subsequently applied to the percolating network of silver nanofibres using the SPIN 150 spin coater (acceleration: 500 rpm, speed 5000 rpm, time 100 s). The latter is vulcanized at 150° C. for a time of 5 minutes.

The properties of the transparent and conducting electrode are as follows:

| Properties | Results | |
|---|---|---|
| Transmission (550 nm, %) | 80% | |
| Transmission (mean over the | 79% | |
| visible range 400-1000 nm, %) | | |
| Surface resistance (Ω/□) | 30 | Ω/□ |
| Density of silver nanofibres (dₘᵢₙ, | 0.19 | μg/cm² |
| μg/cm²) | | |
| Density of silver nanofibres (dₘₐₓ, | 0.96 | μg/cm² |
| μg/cm²) | | |

The multilayer transparent conducting electrode according to the invention thus makes it possible, by virtue of the presence of the electrical homogenization layer, to protect the conducting network of metal nanofilaments without damaging it, which in fact extends the lifetime and the durability of the electrode. Furthermore, this electrical homogenization layer makes possible homogenization of the surface conductivity and also a decrease in the roughness, in fact enhancing the performance of the multilayer transparent conducting electrode.

1. A multilayer transparent conducting electrode, comprising a substrate layer, an adhesion layer, a percolating network of metal nanofilaments and an electrical homogenization layer, characterized in that the electrical homogenization layer comprises:
an elastomer having a glass transition temperature Tg of less than 20° C. and/or a thermoplastic polymer having a glass transition temperature Tg of less than 20° C. and/or a polymer,
an optionally substituted polythiophene conducting polymer, and nanometric conducting or semiconducting fillers.

2. The multilayer transparent conducting electrode according to claim 1, characterized in that the electrical homogenization layer also comprises particles of crosslinked or noncrosslinked polymer chosen from functionalized or nonfunctionalized particles of polystyrene, polycarbonate or polymethylenemelamine, said particles of noncrosslinked polymer having a glass transition temperature Tg of greater than 80° C., particles of glass, particles of silica and/or particles of metal oxides chosen from the following metal oxides: ZnO, MgO, MgAl₂O₄, or particles of borosilicate.

3. The multilayer transparent conducting electrode according claim 1, characterized in that it exhibits a mean transmission over the visible spectrum of greater than 75%.

4. The multilayer transparent conducting electrode according to claim 1, characterized in that it exhibits a surface resistance of less than 1000Ω/.

5. The multilayer transparent conducting electrode according to claim 1, characterized in that the adhesion layer is made of nitrile rubber.

6. The multilayer transparent conducting electrode according to claim 1, characterized in that the percolating network of metal nanofilaments is multilayer.

7. The multilayer transparent conducting electrode according claim 1, characterized in that the network of metal nanofilaments has a density of metal nanofilaments of between 0.01 μg/cm² and 1 mg/cm².

8. The multilayer transparent conducting electrode according to claim 1, characterized in that the metal nanofilaments are nanofilaments of noble metals.

9. The multilayer transparent conducting electrode according to claim 1, characterized in that the metal nanofilaments are nanofilaments of nonnoble metals.

10. The multilayer transparent conducting electrode according to claim 1, characterized in that the substrate is chosen from glass and transparent flexible polymers.

11. A process for the manufacture of a multilayer transparent conducting electrode, the process comprising:
i) providing a substrate layer,
ii) applying an adhesion layer to the substrate,
iii) applying a suspension of metal nanofilaments in an organic solvent to the adhesion layer,
iv) evaporating the organic solvents from the suspension of metal nanofilaments,
v) applying a composition forming the electrical homogenization layer to the metal nanofilaments and comprising:
(a) at least a dispersion or suspension of elastomer having a glass transition temperature Tg of less than 20° C. and/or of thermoplastic polymer having a glass transition temperature Tg of less than 20° C., and/or a polymer solution,
(b) at least an optionally substituted polythiophene conducting polymer,
(c) nanometric conducting or semiconducting fillers in dispersion or in suspension in water and/or in a solvent,
vi) evaporating the solvents from the composition forming the electrical homogenization layer by drying at a temperature of between 25 and 80° C., the drying temperature necessarily having to be, when the polymer particles (c) are particles of noncrosslinked polymer, less than the glass transition temperature Tg of the particles of noncrosslinked polymer present in the composition applied during the preceding stage, followed by crosslinking of the said electrical homogenization layer.

12. The process of manufacture according to claim 11, characterized in that the electrical homogenization layer also comprises particles of crosslinked or noncrosslinked polymer chosen from functionalized or nonfunctionalized particles of polystyrene, polycarbonate or polymethylenemelamine, the particles of noncrosslinked polymer exhibiting a glass transition temperature Tg of greater than 80° C., particles of glass, particles of silica, and/or particles of metal oxides chosen from the following metal oxides: ZnO, MgO, MgAl₂O₄, or particles of borosilicate.

13. The process of manufacture according to claim 11, characterized in that the substrate is chose from glass and transparent flexible polymers.

14. The process of manufacture according to claim 11, characterized in that the adhesion layer comprises nitrile rubber.

15. The process of manufacture according to claim 11, characterized in that the stages of application of a suspension of metal nanofilaments to the adhesion layer in an organic solvent and evaporation of the organic solvents from the suspension of metal nanofilaments are carried out several times in succession obtain a multilayer percolating network of metal nanofilaments.

16. The process of manufacture according to claim 11, characterized in that the metal nanofilaments are nanofilaments of noble metals.

17. The process of manufacture according to claim 11, characterized in that the metal nanofilaments are nanofilaments of nonnoble metals.
